(19) United States
(12) Patent Application Publication
(10) Pub. No.: US 2026/0147967 A1
(43) Pub. Date: May 28, 2026

(54) HYDROCARBON EXTRACTION SITE MODELING

(71) Applicant: Clean Connect AI, Inc., Windsor, CO (US)

(72) Inventors: Janna Broderson, Windsor, CO (US); Erik Ryan Davies, Windsor, CO (US); Mehdi Korjani, Pasadena, CA (US); David A. Conley, Windsor, CO (US)

(21) Appl. No.: 19/402,106

(22) Filed: Nov. 26, 2025

Related U.S. Application Data
(60) Provisional application No. 63/725,734, filed on Nov. 27, 2024.

(51) Int. Cl. G06F 30/28

(52) U.S. Cl. CPC G06F 30/28

(57) ABSTRACT

Various embodiments of the present technology relate to solutions for hydrocarbon extraction systems. In some examples, a system models a hydrocarbon extraction site. The system comprises processing circuitry. The processing circuitry obtains a topographically accurate map of the hydrocarbon extraction site and populates the map with digital assets that correspond to equipment and a monitoring system in the hydrocarbon extraction site. The processing circuity obtains sensor data for the equipment from on-site sensors and obtains image data depicting the site from the monitoring system. The processing circuity converts the sensor data into a format interpretable by a thermodynamic model and provides the converted data to the model. The processing circuity receive an output from the model that comprises process values for the equipment. The processing circuity adds the process values and the image data to the digital assets to create a model of the hydrocarbon extraction site.

### CROSS-REFERENCE TO RELATED APPLICATIONS

This U.S. Patent Application claims priority to U.S. Provisional Patent Application 63/725,734 titled “HYDROCARBON EXTRACTION SITE MODELING” which was filed on Nov. 27, 2024. U.S. Provisional Patent Application 63/725,734 is incorporated into this U.S. Patent Application in its entirety.

### TECHNICAL FIELD

Various embodiments of the present technology relate to hydrocarbon extraction technologies, and more specifically, to modeling hydrocarbon extraction sites.

### BACKGROUND

Hydrocarbon extraction systems comprise machinery and equipment configured to extract petroleum, natural gas, and other types of chemicals for use in energy generation, heating, and chemical production applications. Hydrocarbon extraction systems comprise extraction equipment, transfer equipment, and storage equipment. The extraction equipment is configured to remove hydrocarbons from subterranean reservoirs. Examples of extraction equipment include drilling rigs and hydraulic fracturing devices. The transfer equipment is configured to transport the extracted hydrocarbons between different geographic locations. Examples of transfer equipment include pipelines and tanker trucks. The storage equipment is configured to store hydrocarbons. Examples of storage equipment include bullet tanks and storage vessels. Operators often need to survey the hydrocarbons extraction equipment, storage equipment, and transfer equipment.

Conventional methods to monitor hydrocarbon extraction, storage, and transfer equipment use surveillance cameras and on-site human operators to track the status of the equipment. The surveillance cameras are mounted at elevation and positioned to view the equipment of interest. The cameras generate video depicting the equipment and transfer the video to a centralized monitoring station. Additionally, on-site sensors may measure and report variables that describe the operation of the hydrocarbon extraction, storage, and transfer equipment like temperature, pressure, and flowrate to the centralized monitoring station. Unfortunately, conventional centralized monitoring stations do not efficiently or effectively represent the operations of the hydrocarbon extraction, storage, and transfer equipment.

### Overview

This Overview is provided to introduce a selection of concepts in a simplified form that are further described below in the Technical Description. This summary is not intended to identify key features or essential features of the claimed subject matter, nor is it intended to be used as an aid in determining the scope of the claimed subject matter.

Various embodiments of the present technology relate to solutions for monitoring hydrocarbon extraction and storage environments. Some embodiments comprise a method to model a hydrocarbon extraction site. The method comprises obtaining a topographically accurate map of the hydrocarbon extraction site. The method further comprises populating the map with digital assets that correspond to equipment and a monitoring system in the hydrocarbon extraction site. The method further comprises obtaining sensor data for the equipment from sensors in the hydrocarbon extraction site. The method further comprises obtaining image data depicting the hydrocarbon extraction site from the monitoring system in the hydrocarbon extraction site. The method further comprises converting the sensor data into a format interpretable by a thermodynamic model and providing the converted sensor data to the thermodynamic model. The method further comprises receiving an output from the thermodynamic model that comprises process values that depict the operation of the equipment of the hydrocarbon extraction site. The method further comprises adding the process values from the output of the thermodynamic model and the image data to corresponding ones of the digital assets to create a model of the hydrocarbon extraction site.

Some embodiments comprise a system to model a hydrocarbon extraction site. The system comprises processing circuitry. The processing circuitry obtains a topographically accurate map of the hydrocarbon extraction site. The processing circuity populates the map with digital assets that correspond to equipment and a monitoring system in the hydrocarbon extraction site. The processing circuity obtains sensor data for the equipment from sensors in the hydrocarbon extraction site. The processing circuity obtains image data depicting the hydrocarbon extraction site from the monitoring system in the hydrocarbon extraction site. The processing circuity convert the sensor data into a format interpretable by a thermodynamic model and provides the converted sensor data to the thermodynamic model. The processing circuity receives an output from the thermodynamic model that comprises process values that depict the operation of the equipment of the hydrocarbon extraction site. The processing circuity adds the process values from the output of the thermodynamic model and the image data to corresponding ones of the digital assets to create a model of the hydrocarbon extraction site.

Some embodiments comprise a non-transitory computer-readable medium stored thereon instructions to model a hydrocarbon extraction site. The instructions, in response to execution, cause a system comprising a processor to perform operations. The operations comprise obtaining a topographically accurate map of the hydrocarbon extraction site. The operations further comprise populating the map with digital assets that correspond to equipment and a monitoring system in the hydrocarbon extraction site. The operations further comprise obtaining sensor data for the equipment from sensors in the hydrocarbon extraction site. The operations further comprise obtaining image data depicting the hydrocarbon extraction site from the monitoring system in the hydrocarbon extraction site. The operations further comprise converting the sensor data into a format interpretable by a thermodynamic model and providing the converted sensor data to the thermodynamic model. The operations further comprise receiving an output from the thermodynamic model that comprises process values that depict the operation of the equipment of the hydrocarbon extraction site. The operations further comprise adding the process values from the output of the thermodynamic model and the image data to corresponding ones of the digital assets to create a model of the hydrocarbon extraction site.

### DESCRIPTION OF THE DRAWINGS

Many aspects of the disclosure can be better understood with reference to the following drawings. The components in the drawings are not necessarily drawn to scale. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 illustrates an example of a system that models a hydrocarbon extraction site.

FIG. 2 illustrates an example operation of the system to model the hydrocarbon extraction site.

FIG. 3 illustrates an example of a user interface to model a hydrocarbon extraction site.

FIG. 4 illustrates another example of the user interface to model a hydrocarbon extraction site.

FIG. 5 illustrates another example of the user interface to model a hydrocarbon extraction site.

FIG. 6 illustrates another example of the user interface to model a hydrocarbon extraction site.

FIG. 7 illustrates another example of the user interface to model a hydrocarbon extraction site.

FIG. 8 illustrates another example of the user interface to model a hydrocarbon extraction site.

FIG. 9 illustrates another example of the user interface to model a hydrocarbon extraction site.

FIG. 10 illustrates another example of the user interface to model a hydrocarbon extraction site.

FIG. 11 illustrates another example of the user interface to model a hydrocarbon extraction site.

FIG. 12 illustrates another example of the user interface to model a hydrocarbon extraction site.

FIG. 13 illustrates another example of the user interface to model a hydrocarbon extraction site.

FIG. 14 illustrates another example of the user interface to model a hydrocarbon extraction site.

FIG. 15 illustrates another example of the user interface to model a hydrocarbon extraction site.

FIG. 16 illustrates another example of the user interface to model a hydrocarbon extraction site.

FIG. 17 illustrates another example of the user interface to model a hydrocarbon extraction site.

FIG. 18 illustrates another example of the user interface to model a hydrocarbon extraction site.

FIG. 19 illustrates another example of the user interface to model a hydrocarbon extraction site.

FIG. 20 illustrates another example of the user interface to model a hydrocarbon extraction site.

FIG. 21 illustrates another example of the user interface to model a hydrocarbon extraction site.

FIG. 22 illustrates another example of the user interface to model a hydrocarbon extraction site.

FIG. 23 illustrates another example of the user interface to model a hydrocarbon extraction site.

FIG. 24 illustrates another example of the user interface to model a hydrocarbon extraction site.

FIG. 25 illustrates an example of a computing system that may be used with various embodiments of the present technology.

The drawings have not necessarily been drawn to scale. Similarly, some components or operations may not be separated into different blocks or combined into a single block for the purposes of discussion of some of the embodiments of the present technology. Moreover, while the technology is amendable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

The following description and associated figures teach the best mode of the invention. For the purpose of teaching inventive principles, some conventional aspects of the best mode may be simplified or omitted. The following claims specify the scope of the invention. Note that some aspects of the best mode may not fall within the scope of the invention as specified by the claims. Thus, those skilled in the art will appreciate variations from the best mode that fall within the scope of the invention. Those skilled in the art will appreciate that the features described below can be combined in various ways to form multiple variations of the invention. As a result, the invention is not limited to the specific examples described below, but only by the claims and their equivalents.

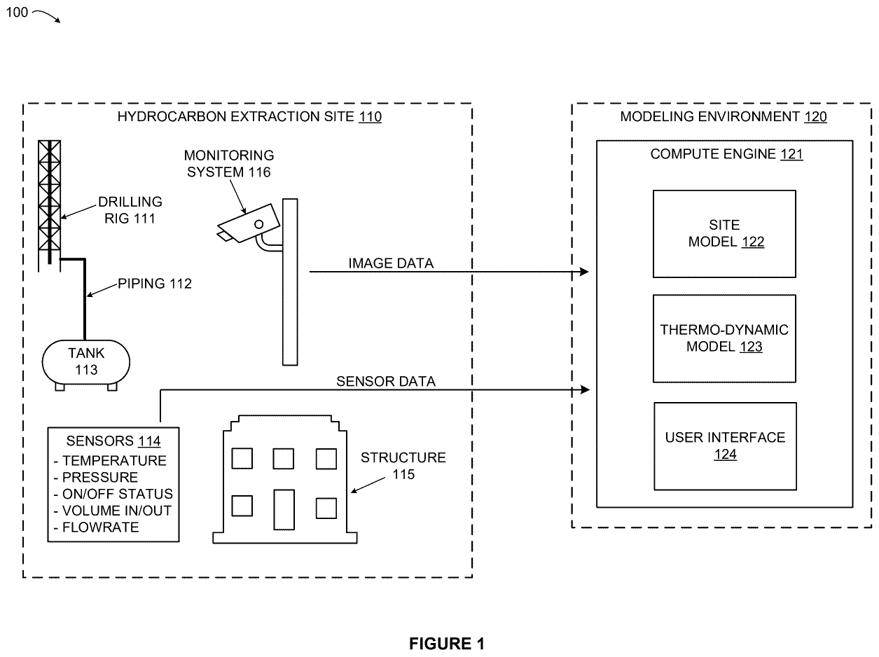

FIG. 1 illustrates an example of hydrocarbon extraction and monitoring environment 100 to model a hydrocarbon extraction site. Environment 100 performs services like hydrocarbon storage, hydrocarbon transfer, hydrocarbon extraction, hydrocarbon leak detection, hydrocarbon tank fill level detection, hydrocarbon extraction site monitoring, and hydrocarbon extraction site modeling. Environment 100 comprises hydrocarbon extraction site 110 and modeling environment 120. Hydrocarbon extraction site 110 comprises drilling rig 111, piping 112, tank 113, sensors 114, structure 115, and monitoring system 116. Hydrocarbon extraction site 110 typically includes additional components like vehicles, refining systems, environmental protection systems, chemical reactors, and the like, however the additional components are omitted for clarity. Hydrocarbon extraction site 110 may extract, store, transfer, and/or process hydrocarbons like crude oil, refined petroleum, natural gas, petrochemicals, petroleum based chemical products, other chemicals obtained during hydrocarbon extraction (e.g., helium), oil sands, oil shale, and the like. Modeling environment 120 comprises compute engine 121. Compute engine 121 comprises site model 122, thermodynamic model 123, and user interface 124. In other examples, environment 100 may include fewer or additional components than those illustrated in FIG. 1. Likewise, the illustrated components of environment 100 may include fewer or additional components, assets, or connections than shown. Compute engine 120 may be representative of a single computing apparatus or multiple computing apparatuses.

Various examples of system operation and configuration are presented herein, in some examples, modeling environment 120 is representative of an off-site computing system to model extraction site 110. Modeling environment 120 may model site 110 based on a topographically accurate Three Dimensional (3D) map of the location of extraction site 110, scale 3D digital models of the components of site 110, the sensor data received from sensors 114, the monitoring data received from monitoring system 116, and/or other data. The resulting model (i.e., site model 122) may be used by operators to assess the current status of extraction site 110, locate the presence of leaks or other abnormalities, and plan responses to the detected abnormalities. In some examples, modeling environment 120 may output predictions of abnormalities based on the received data to allow operators to take corrective action before the abnormality occurs.

Compute engine 121 is representative of one or more computing systems that comprise processing circuitry, one or more data storage systems, and one or more communication transceivers. Compute engine 121 may also include other components like user interfaces and power supply. Examples of compute engine 121 may include server computers and data storage devices deployed on-premises, in the cloud, in a hybrid cloud, or elsewhere, by service providers such as enterprises, organizations, individuals, and the like. Compute engine 121 may host a virtualized computing system like Network Function Virtualization Infrastructure (NFVI), Containers-as-a-Service (CaaS), and the like. For example, models 122 and 123 may be implemented as virtual machines, containers, or another type of virtual/containerized computing system. Compute engine 121 may rely on the physical connections provided by one or more other network providers such as transit network providers, Internet backbone providers, and the like to communicate with and external systems. The one or more computing devices of compute engine 121 may reside in a single device or may be distributed across multiple devices and may be a discrete system or could be integrated within other systems, including other systems within environment 100.

Site model 122 comprises a scaled and navigable 3D model of extraction site 110 populated with sensor and monitoring data received from extraction site 110. Site model 122 comprises a Three Dimensional (3D) topographical map of the geographic area of extraction site 121. The map is populated with scale 3D digital models of drilling rig 111, pipeline 112, tank 113, sensors 114, structure 115, monitoring system 116, and/or other equipment in extraction site 110. The 3D scale models may be positioned at locations on the 3D topographical map that correspond to the GPS coordinates of their real-world equivalents. However, the 3D scale models are moveable on the 3D map to allow a user to plan site additions, view alternative site configurations, and the like. Site model 122 overlays the 3D models with sensor and monitoring data received from extraction site 110 after processing by thermodynamic model 123. For example, site model 122 may overlay an on/off status on the 3D model of drilling rig 111, a flowrate onto the 3D model of pipeline 112, and a temperature, pressure, and fill percent on the 3D model of tank 113. Site model 122 updates the overlayed data values in response to receiving new data from extraction site 110 to provide an up-to-date view of extraction site 110. The overlayed data values are configurable from a set of available data value types. For example, site model 122 may comprise selectable options to define which data values are to be overlayed onto which 3D models (e.g., a user may elect to overlay flowrate and to not overlay temperature on the 3D model of pipeline 112).

When monitoring system 116 detects or predicts an abnormality in site 110, site model 122 overlays an alert notice on the corresponding 3D models to indicate the presence of the abnormality/prediction. For example, when monitoring system 116 detects the presence of a gas leak from tank 113, site model 122 may overlay an alert indication on the 3D model of tank 113 to alert operators. Site model 122 may provide a ground level view of extraction site 110. For example, site model 122 may comprise a walkable mode which allows a user to move around site model 122 as if they were walking in extraction site 110. Site model 122 comprises options to indicate the field of view of monitoring system 121. For example, site model 122 may shade a first area of the 3D map with a first color to indicate the camera can view the first area and shade a second area of the 3D map with a second color to indicate the camera cannot view second area. Site model 122 may include a windowed video feed for the 3D model of monitoring system 120 based on video data received from monitoring system 116 to provide a live feed of extraction site 116. Site model 122 may comprise a layered view which allows users to toggle which 3D models are present in site model 122. For example, a user may select an option to hide or view the 3D model for pipeline 112.

Thermodynamic model 123 comprises any model implemented within environment 100 as described herein to track the mass, volumetric, and/or energy inputs and outputs in extraction site 110. For example, thermodynamic model 123 may be used to confirm the volumetric flow rate of natural gas through piping 112 reported by sensors 114. Thermodynamic model 123 comprises one or more algorithms to balance material (e.g., hydrocarbons, water, air) and energy inputs and outputs in extraction site 110. For example, thermodynamic model 123 may track mass inputs, stored reserves, and mass outputs in tanks 113 to determine if any discrepancies exist. In examples where a leak is present in tank 113 and/or pipeline 112, the input mass/volume and the output mass/volume reported by sensors 114 may not align. Thermodynamic model 123 may input the inputs, outputs, stored reserves, and stored capacity into its algorithms to determine if a discrepancy exists. The algorithms may take additional inputs like compressibility, density, molar mass, temperature, pressure, and/or other physical attributes to model mass and energy flow in extraction site 110, detect input/output discrepancies, and/or perform some other thermodynamic modeling operation. The outputs from model 123 may be compared to the monitoring and sensor data received from site 110 to determine when extraction site 110 is leak free, the detected leaks are below a tolerance threshold, and detect malfunctions or calibration errors in sensors 114. Thermodynamic model 123 provides its outputs to site model 122 for overlay on the 3D models in site model 122.

User interface 124 comprises one or more display screens, touch screens, keyboards, computer mice, touch pads, and the like to facilitate interaction between compute engine 121 and users. User interface 124 presents a Graphical User Interface (GUI) that displays site model 122 and optionally thermodynamic model 123. The GUI may comprise a number of selectable options to navigate, add/remove 3D models, move 3D models, view the status/data values of the 3D models, select which data values are to be displayed, and/or other functions in site model 122.

Advantageously, environment 100 effectively and efficiently models extraction site 110. Moreover, site model 122 provides a navigable and up-to-date view of extraction site 110 that allows operators to view the status, view detected abnormalities, plan additions, and assess locations of monitoring systems in extraction site 110.

Drilling rig 111 is representative of one or more pieces of hydrocarbon extraction equipment. Hydrocarbon extraction equipment accesses and captures hydrocarbons from subterranean reservoirs for use as fuel, chemical products, refining, and the like. Drilling rig 111 may comprise a hydraulic fracking rig, a drilling rig, an oil well, a natural gas well, oil sands extraction machinery, and the like. Pipeline 112 is representative of one or more pieces of hydrocarbon transfer equipment. Hydrocarbon transfer equipment transports hydrocarbons between geographic regions, typically from extraction or storage sites to refining facilities, chemical production facilities, energy production facilities, households for consumer use, other storage sites, and the like. As illustrated in FIG. 1, pipeline 112 couples drilling rig 111 to tank 113. For example, hydrocarbons (e.g., natural gas) extracted by drilling rig 111 may be transported to tank 113 via pipeline 112. Pipeline 112 may comprise additional components like pressurizers, sampling stations, valves, flaring systems, and the like. In some examples, extraction site 110 may comprise additional pipelines to transfer other materials like water, air, fuel/air mixtures, and the like. In addition to pipeline 112, extraction site 110 may comprise other types of hydrocarbon transfer equipment like tanker trucks, railcars, and the like. Storage tank 113 is representative of one or more pieces of hydrocarbon storage equipment. Hydrocarbon storage equipment holds extracted hydrocarbons before being transported to downstream systems like refining facilities, chemical production facilities, energy production facilities, consumer use, and the like. Exemplary hydrocarbon storage equipment includes bullet tanks, Liquified Natural Gas (LNG) storage tanks, gasholders, storage vehicles, and/or other types of storage systems. Structure 115 is representative of one or more buildings present in extraction site 110. Exemplary buildings include offices, equipment storage facilities, warehouses, sensor housing, equipment housing, equipment scaffolding, and the like.

Sensors 114 are representative of devices to measure and report metrics describing the operation and status of the equipment that composes extraction site 110. As illustrated in FIG. 1, sensors 114 measure hydrocarbon inputs, hydrocarbon outputs, equipment temperature, equipment pressure, equipment on/off status, hydrocarbon volume, and hydrocarbon flowrate, however sensors 114 may measure additional metrics like equipment location, equipment type, and/or other data for the equipment in extraction site 110. Sensors 114 comprise devices like thermometers, pressure gauges, flowmeters, and on/off indicators, however in other examples, sensors 114 may comprise additional or different sensors (e.g., Global Positioning System (GPS) sensors, equipment Identifier (ID) devices, wind gauges, hygrometers, cameras, etc.) than those illustrated in FIG. 1. Sensors 114 are operatively coupled to drilling rig 111, pipeline 112, tank 113, and structure 114, and optionally to monitoring system 116. Sensors 114 interact with the other equipment in extraction site 110 to generate sensor data and report the sensor data to modeling environment 120. Sensors 114 also provide environmental data like temperature, pressure, wind speed, wind direction, clouds, visibility, humidity, dew point, and the like to modeling environment 120.

Monitoring system 116 is representative of one or more computing devices and imaging devices to monitor the various components of extraction site 110, measure fill level in tank 113, detect leaks (e.g., from pipeline 112, tank 113, etc.), and the like. In this example, monitoring system 116 comprises a camera to generate infrared and/or optical video images depicting extraction site 110, however in other examples, the camera(s) may employ a different type of imaging technology like ultraviolet. It should be understood that gas leaks are difficult to view in the visual light spectrum. As such, monitoring system 116 typically comprises imaging technology for generating images in non-visible spectrums (e.g., infrared). Although monitoring system 116 is illustrated as comprising a single imaging device, in some examples monitoring system 116 may comprise multiple imaging devices. The multiple cameras of monitoring system 116 may include a combination of optical, infrared, and/or laser cameras and imaging devices to facilitate extraction site monitoring.

Monitoring system 116 may also include distance measuring devices like laser rangefinders to estimate the distance between the other equipment in extraction site 110 and monitoring system 116. Monitoring system 116 is attached to a mounting structure. Although the mounting structure is depicted as on pole, monitoring system 116 may comprise a different type of mounting structure or may use no mounting structure at all. Monitoring system 116 may include a pan and tilt system that moves the camera in multiple directions and orientations to cover a wider range and stabilize the field of view. Monitoring system 116 may comprise a controller to move the camera to pre-defined views and control the direction of monitoring system 116 to provide a 360-degree field of view. The controller may receive instructions (e.g., from the onboard computer) and responsively position the camera of monitoring system 116.

The one or more computing devices of monitoring system 116 receive video data from the camera(s) and process the video data to identify the presence of leaks, confirm sensor outputs from sensors 114, measure the fill level of tank 113, report monitoring data to modeling environment 120, and/or perform other monitoring operations. Monitoring system 116 may host one or more machine learning models, artificial intelligence systems, or other systems to process video data captured by monitoring system 116. For example, the one or more computing devices of monitoring system 116 may comprise an application specific circuit configured to implement a machine learning model. Monitoring system 116 may additionally host interfacing applications to receive and preprocess the video and telemetry data from the camera and sensors 114. The interfacing applications may vectorize the received data to configure the data for ingestion by the model. Vectorization comprises a feature extraction process to numerically represent the received data. In some examples, monitoring system 116 may generate feature vectors that represent individual pixels of video data received from the camera.

The machine learning model(s) hosted by monitoring system 116 comprises any machine learning model implemented within environment 100 as described herein to detect the presence of gas leaks, measure tank fill level, confirm sensor outputs, and/or perform some other monitoring operation. A machine learning model comprises one or more machine learning algorithms that are trained based on historical data and/or other types of training data. A machine learning model may employ one or more machine learning algorithms through which data can be analyzed to identify patterns, make decisions, make predictions, or similarly produce output for environment 100. The machine learning model may comprise algorithms to detect background environments, to detect motion, to detect equipment, to classify gas leaks, measure fill levels, and/or other types of machine learning algorithms. Examples of machine learning algorithms that may be employed solely or in conjunction with one another include Three Dimensional (3D) deep leaning models, 3D convolutional neural networks, times series convolutional deep learning, transformers, multi-layer perceptron, long term short memory, and attention based deep learning model. Other exemplary machine learning algorithms include artificial neural networks, nearest neighbor methods, ensemble random forests, support vector machines, naïve Bayes methods, linear regressions, or similar machine learning techniques or combinations thereof capable of predicting output based on input data. Monitoring system 116 reports video data depicting site 110, leak indications, fill level indications, and the like to modeling environment 120.

Sensors 114, monitoring system 116, and compute engine 121 communicate over various communication links using communication technologies like Institute of Electrical and Electronic Engineers (IEEE) 802.3 (Ethernet), IEEE 802.11 (Wifi), Bluetooth, Time Division Multiplex (TDM), Data Over Cable System Interface Specification (DOCSIS), Internet Protocol (IP), General Packet Radio Service Transfer Protocol (GTP), and/or some other type of wireline and/or wireless networking protocol. The communication links comprise metallic links, glass fibers, radio channels, or some other communication media. The links use Ethernet, Wifi, virtual switching, inter-processor communication, bus interfaces, and/or some other data communication protocols.

Sensors 114, monitoring system 116, and compute engine 121 comprise microprocessors, software, memories, transceivers, bus circuitry, and the like. The microprocessors comprise Central Processing Units (CPUs), Graphical Processing Units (GPUs), Digital Signal Processors (DSPs), Application-Specific Integrated Circuits (ASICs), Field Programmable Gate Arrays (FPGAs), analog computing circuits, and/or the like. The memories comprise Random Access Memory (RAM), flash circuitry, Hard Disk Drives (HDDs), Solid State Drives (SSDs), Non-Volatile Memory Express (NVMe) SSDs, and/or the like. The memories store software like operating systems, user applications, networking applications, machine learning applications, and the like. The microprocessors retrieve the software from the memories and execute the software to drive the operation of environment 100 as described herein.

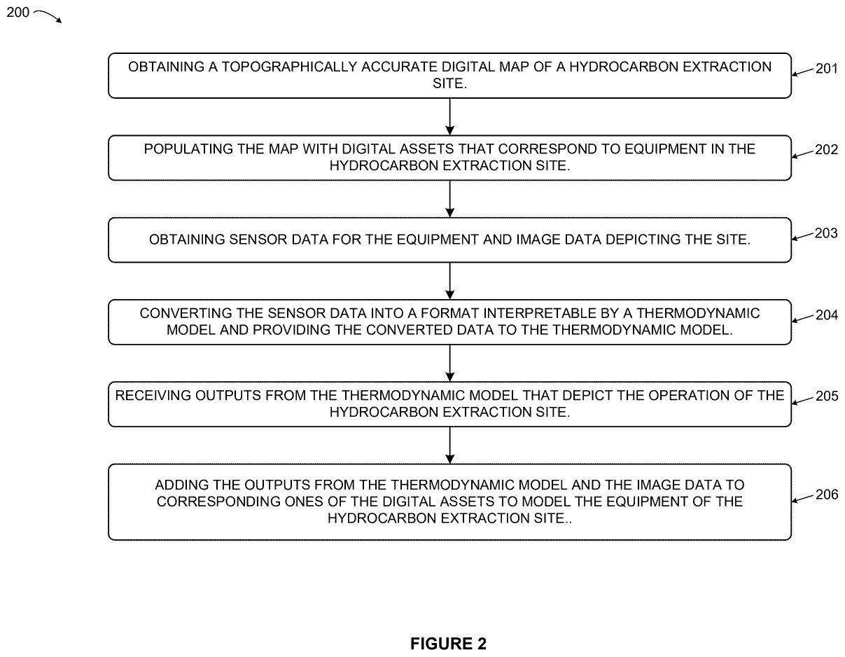

In some examples, environment 100 implements process 200 illustrated in FIG. 2. It should be appreciated that the structure and operation of environment 100 may differ in other examples.

FIG. 2 illustrates an example process 200. Process 200 comprises a hydrocarbon extraction site modeling process. In other examples, process 200 may differ. Process 200 may be implemented in program instructions in the context of any of the software applications, imaging components, module components, machine learning components, or other such elements of one or more computing devices. The program instructions direct the computing device(s) to operate as follows, referred to in the singular for the sake of clarity. Process 200 may differ in other examples.

The operations of process 200 comprise obtaining a topographically accurate digital map of a hydrocarbon extraction site (step 201). The operations further comprise populating the map with digital assets that correspond to equipment and a monitoring system in the hydrocarbon extraction site (step 202). The operations further comprise obtaining sensor data for the equipment from sensors and obtaining image data depicting the hydrocarbon extraction site from the monitoring system in the hydrocarbon extraction site (step 203). The operations further comprise converting the sensor data into a format interpretable by a thermodynamic model and providing the converted sensor data to the thermodynamic model (step 204). The operations further comprise receiving an output from the thermodynamic model that comprises process values that depict the operation of the equipment of the hydrocarbon extraction site (step 205). The operations further comprise adding the process values from the output of the thermodynamic model and the image data to corresponding ones of the digital assets to create a model of the hydrocarbon extraction site (step 206).

Referring back to FIG. 1, environment 100 includes a brief example of process 200 as implemented by the various hardware and software components that compose environment 100. In some examples, compute engine 121 accesses a data repository to retrieve a 3D topographical map of the geographic area where extraction site 110 is located (step 201). For example, compute engine 121 may interact with a satellite mapping service to retrieve the 3D map. Compute engine 121 creates site model 122 using the 3D map and displays site model 122 via user interface 124. Compute engine 121 receives a series of user inputs that select and position 3D models of drilling rig 111, pipeline 112, tank 113, sensors 114, structure 115, and monitoring system 116 onto the 3D map at locations that correspond to the locations of the real-world equivalents. Compute engine 121 populates site model 122 with the 3D models based on the user inputs (step 202). For example, compute engine 121 may receive a series of drag-and-drop inputs via user interface 124 that drive compute engine 121 to populate the 3D map with the 3D scale models at user selected locations.

Sensors 114 sense drilling rig 111, pipeline 112, and tank 113 and generate sensor data describing their operations. Sensors 114 sense the on/off status and pressure of drilling rig 111. Sensors 114 sense the volumetric flows, temperature, and pressure of hydrocarbons through pipeline 112 and into/out of tank 113. For example, sensors 114 may comprise flowmeters at the input and output valves of tank 113 and generate metrics like cubic feet or rates like cubic feet per day. Sensors 114 may generate additional telemetry data like temperature, pressure, and venting status for tanks 102-104. Sensors 114 generate environmental data describing windspeed, pressure, temperature, and the like. Sensors 114 transfer the sensor data for delivery to compute engine 121.

Monitoring system 116 views drilling rig 111, pipeline 112, tank 113, sensors 114, and structure 115 and generates optical and infrared video data. Monitoring system 116 provides the video data to its constituent machine learning algorithms. The machine learning algorithms detect the presence of any leaks in extraction site 110 and measure the fill level in tank 113. Typically, the machine learning algorithms detect the presence of gas leaks may identifying motion in infrared video, comparing the motion with known leak characteristics, and collocating the motion with a piece of hydrocarbon storage or transfer equipment. Typically, the machine learning algorithms measure the fill level in tank 113 by correlating temperature differences in the thermal profile of tank 113 with filled and unfilled sections of the vessel. Monitoring system 116 transfers the optical and infrared video data as well as indications for any detected leaks and the fill level of tank 113 for delivery to compute engine 121.

Compute engine 121 receives the monitoring data and the sensor data from monitoring system 116 and sensors 114 respectively (step 203). Generally, the sensor data is in a format native to extraction site 110 and is not interpretable by thermodynamic model 123. Compute engine 121 translates the sensor data from the format native to extraction site 110 to a format interpretable by thermodynamic model 123. For example, the various process variables (e.g., temperature) received from extraction site 110 may be represented by program tags. For each program tag, compute engine may identify the piece of equipment (e.g., pipeline 112) and variable (e.g., flowrate) that the tags represent and select corresponding program tags native to thermodynamic model 123 to represent the process variables.

Compute engine 121 provides the translated sensor data and monitoring data to thermodynamic engine 123 (step 204). Thermodynamic model 123 extracts the total hydrocarbon input volume, total hydrocarbon output volume, tank/pipeline temperature, tank/pipeline pressure, tank fill level, available tank capacity, and drilling rig status into the algorithms. The algorithms model the flow of hydrocarbons and energy through extraction site 110 based on the input conditions. Thermodynamic model 123 produces an output that defines the process variables in extraction site 110. For example, thermodynamic model 123 may produce an output that indicates the temperature, pressure, volumetric flowrate, total input volume, and total output volume of pipeline 112. The output also indicates any discrepancies between the values measured by sensors 114 and monitoring system 116 and the modeled values. For example, if pipeline 112 is leaking, the total input volume and the total output volume may differ, and the output may indicate this discrepancy.

Compute engine 121 receives the monitoring data and the data values output by the thermodynamic model 123 and provides the received data to site model 122 (step 205). Site model 122 associates the process variables for each piece of equipment in extraction site 110 with corresponding ones of the digital models populated on the 3D map of extraction site 110 (step 206). For example, a user may select one of the digital assets and site model 122 may display a window comprising the process variables associated with that 3D model. For example, site model 122 may overlay process variables associated with a 3D model on the 3D model. For the 3D model representing monitoring system 116, site model associates the monitoring data received from monitoring system with that 3D model. For example, a user may click on the 3D model representing monitoring system 116 and site model 122 may display a live feed, video recording, and/or still frame images of the view of monitoring system 116. Compute engine 121 displays site model 121 on user interface 124 to a scaled, accurate, and up-to-date view of extraction site 110.

In some examples, when monitoring system 116 and/or thermodynamic model 123 detect any abnormalities (e.g., gas leaks, mass/volume discrepancies, etc.) in extraction site 110, site model 122 adds alert notifications to 3D models that correspond to the abnormally operating equipment. For example, monitoring system 116 may detect a leak from tank 113 and notify compute engine 121. Compute engine 121 may deliver the notification to site model 122 and site model 122 may overlay a warning symbol onto the 3D model representing tank 113 to indicate the leak along with leak metrics measured by monitoring system 116 like estimated leak flowrate, total leaked volume, leak start time, equipment ID, equipment GPS coordinates, and the like.

In some examples, site model 122 may calculate a field of view for monitoring system 116 and add the field of to the 3D map of extraction site 110. Site model 122 calculates the field of view based on the direction of the monitoring system 116, the topography of extraction site 110, the height of monitoring system 116, and the locations and heights of the other equipment in extraction site 110. Site model 122 may color to the 3D map to indicate the portions of the extraction site 110 within the field of view of monitoring system 116, and the portions of extraction site 110 that are within the field of view of monitoring system 116 but are obstructed (e.g., blocked by structure 115). A user may select and move the 3D model representing monitoring system 116 around the 3D map and site model 122 may update the field of view of monitoring system 116 accordingly. In doing so, site model 122 provides operators with an enhanced ability to plan where to position monitoring system 116 within extraction site 110 to optimize monitoring system 116's field-of-view.

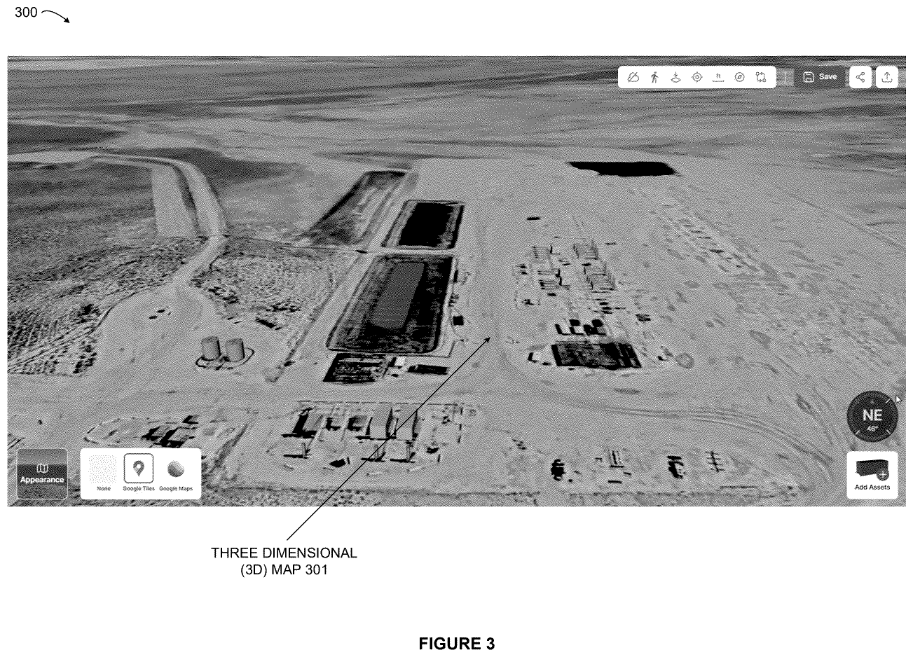

FIGS. 3-24 illustrate examples of user interface 300 to model a hydrocarbon extraction, storage, and transfer site. User interface 300 comprises an example of site model 122, thermodynamic model 123, and user interface 124, however models 122 and 123 and user interface 124 may differ. User interface 300 may be displayed on a display screen of a computing device (e.g., compute engine 121). The computing device may host an application(s) to generate user interface 300 and/or the application may be hosted remotely (e.g., a cloud based computing network may host and the computing device may access the application via a web browser). Now referring to FIG. 3.

FIG. 3 illustrates an example of user interface 300. In some examples, user interface 300 comprises topographically accurate 3D map 301 of a natural gas extraction facility. User interface 300 comprises selectable options for adding 3D digital assets representing the equipment in the natural gas extraction facility, entering a ground level view, distance measuring, saving, exporting, modifying the appearance of the map, and accessing external resources like Google Maps©.

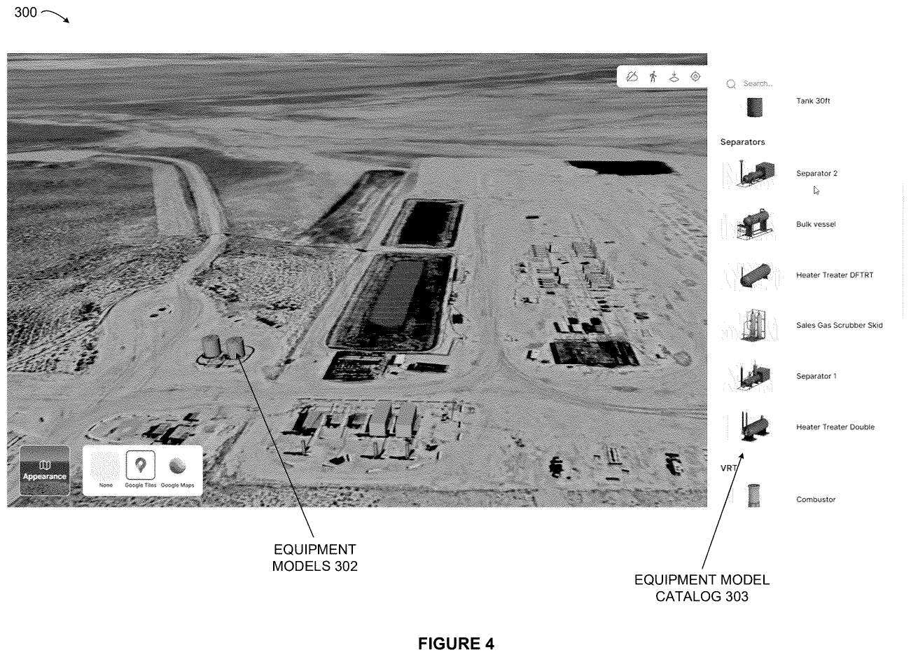

FIG. 4 illustrates an example of user interface 300. In some examples, user interface 300 comprises equipment models 302 populated on 3D map 301. Equipment models 302 comprise 3D scale models of equipment in the natural gas extraction facility. Equipment models 302 are selectable and movable. User interface 300 also comprises equipment model catalog 303 that lists a set of available equipment models. A user may drag-and-drop an equipment model that from catalog 303 onto 3D map 301 at a desired location. For example, a user may place a storage tank equipment model at a location on 3D map 301 that corresponds to the location of a storage tank in the natural gas extraction site.

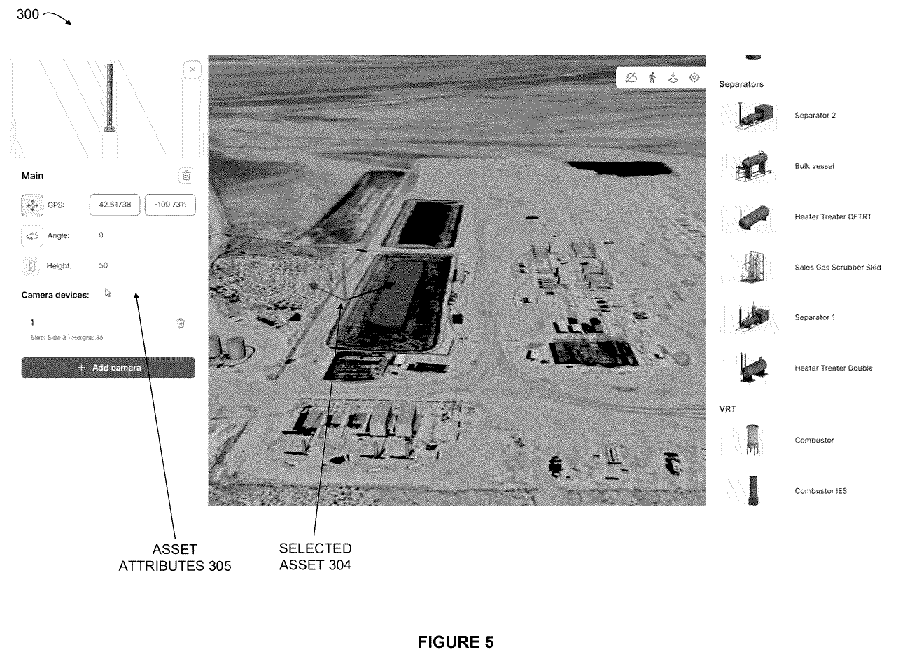

FIG. 5 illustrates an example of user interface 300. In some examples, user interface 300 comprises selected digital equipment model (referred to in this example as a digital asset 304). In this example, a user has selected a digital model representing a monitoring system (e.g., monitoring system 116) in the natural gas extraction environment. User interface 300 indicates the selection by displaying arrows at the base of the selected asset. In response to the selection, user interface 300 displays a window illustrating asset attributes 305. Asset attributes 305 comprise the GPS coordinates, height, and angle of the asset. Asset attributes 305 include a selectable option to add a camera to the monitoring system asset.

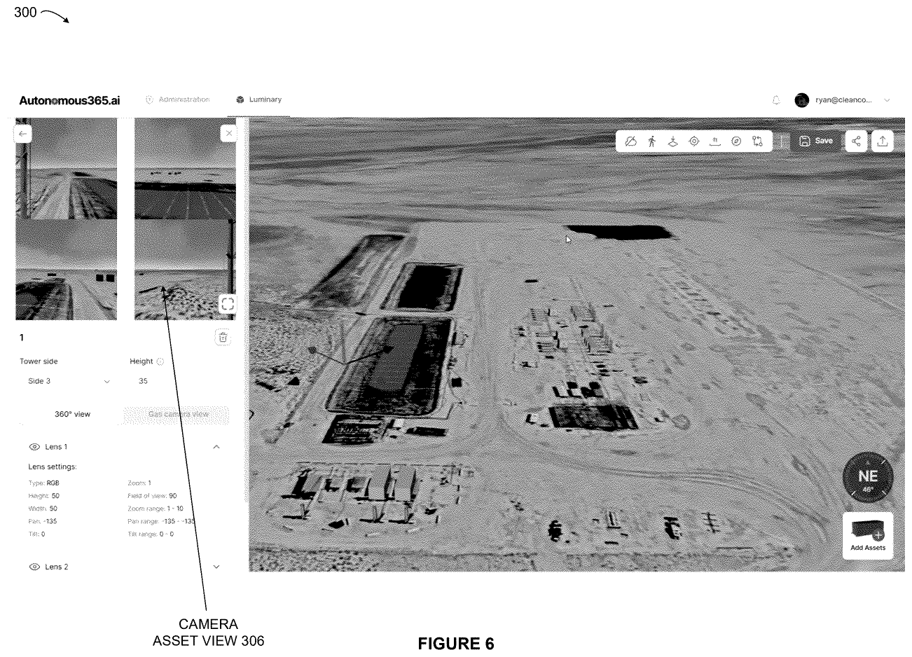

FIG. 6 illustrates an example of user interface 300. In some examples, user interface 300 displays camera view 306 of selected asset 304. For example, a user may select the add camera selectable option illustrated in FIG. 5 and user interface may responsively display camera view306. Camera view 306 depicts 3D map 301 of the natural gas extraction facility from the perspective of visible spectrum cameras mounted to selected asset 304. User interface 300 comprises selectable options to modify the height of the camera, change to a gas camera view (i.e., infrared camera view), and data describing the camera.

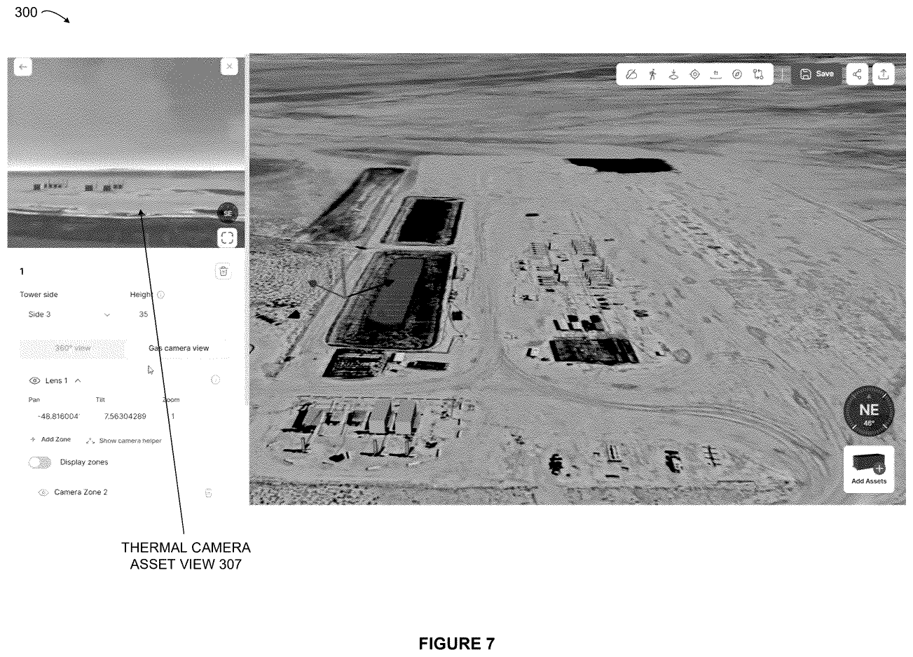

FIG. 7 illustrates an example of user interface 300. In some examples, user interface 300 displays thermal camera view 307 of selected asset 304. For example, a user may select the gas camera view selectable option illustrated in FIG. 6 and user interface 300 may responsively display thermal camera view 307. Thermal camera view 307 depicts 3D map 301 of the natural gas extraction facility from the perspective of a thermal camera mounted to selected asset 304. Advantageously, user interface 300 allows a user to preview the view of a monitoring system in a natural gas extraction facility to plan where to install the monitoring system to detect gas leaks, monitor fill levels, confirm sensor outputs, and/or perform some other type of facility monitoring operation.

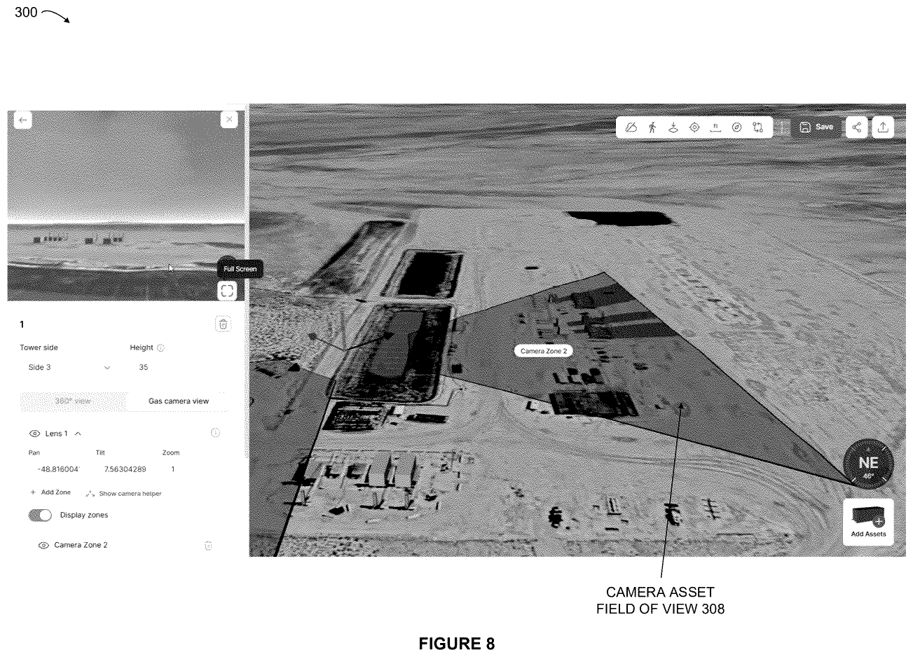

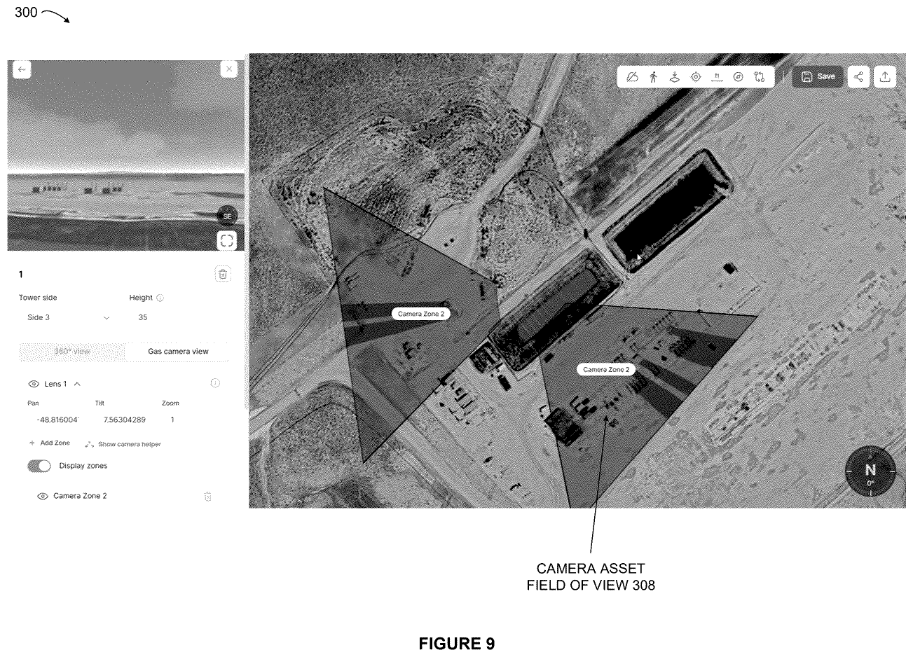

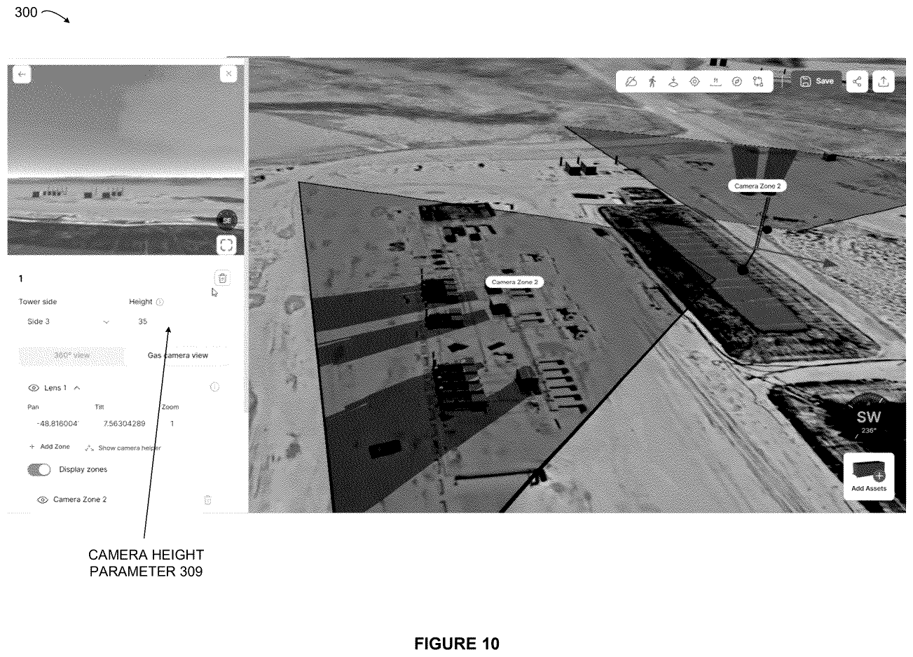

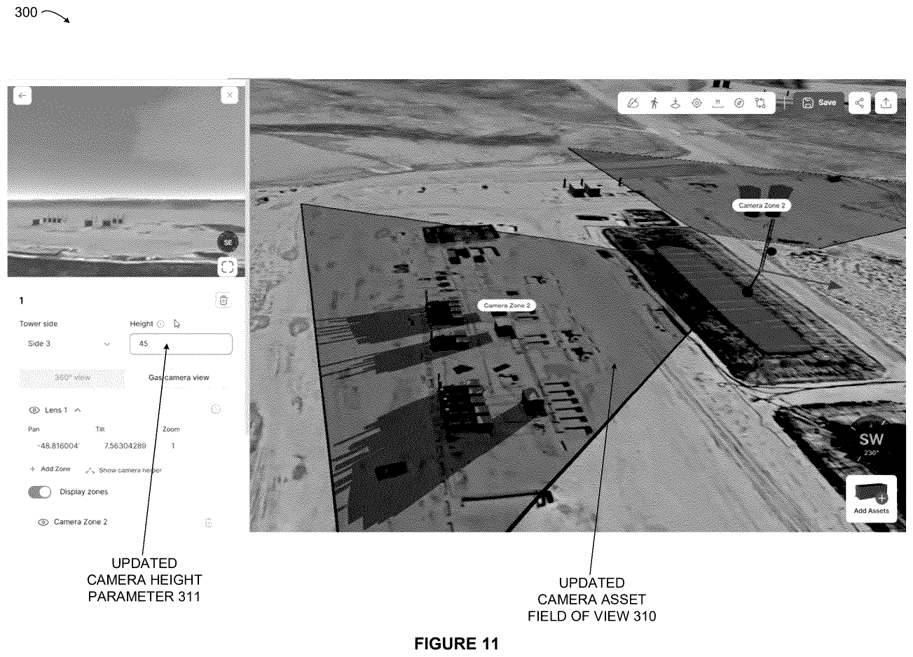

FIG. 8 illustrates an example of user interface 300. In some examples, user interface 300 displays field of view 308 of the camera(s) attached to selected asset 304 onto 3D map 301 of the natural gas extraction facility. The camera's field-of-view is shaded in a first color (e.g., green) on 3D map 301. Portions of 3D map 301 that are within the camera's field-of-view that are obstructed by other objects are shaded in a different color (e.g., red). The field of view is calculated based on the camera type, camera height, camera direction, camera angle, camera location, the topography of 3D map 301. The obstructed portions of the field-of-view are calculated similarly to the field-of-view calculation but considers the height of objects within the camera's field-of-view 308. FIG. 9 illustrates an example of user interface 300. In some examples, user interface displays a bird's eye view of the natural gas extraction site with camera's fields-of-view 308 overlayed onto 3D map 301. FIG. 10 illustrates an example of user interface 300. In some examples, user interface 300 comprises a selectable option to modify the camera height of the selected asset (referred to as camera height parameter 309 in FIG. 10). In this example, the user has input a value of 35 for the camera height. FIG. 11 illustrates an example of user interface 300. In some examples, user interface 300 comprises a selectable option to modify the camera height of the selected asset (depicted as updated camera height parameter 311 in FIG. 11). In this example, the user has updated the camera height value from 35 to 45. In response, user interface 300 updates the field of view overlayed on the 3D map to reflect this height increase (depicted as updated camera asset field of view 310 in FIG. 11).

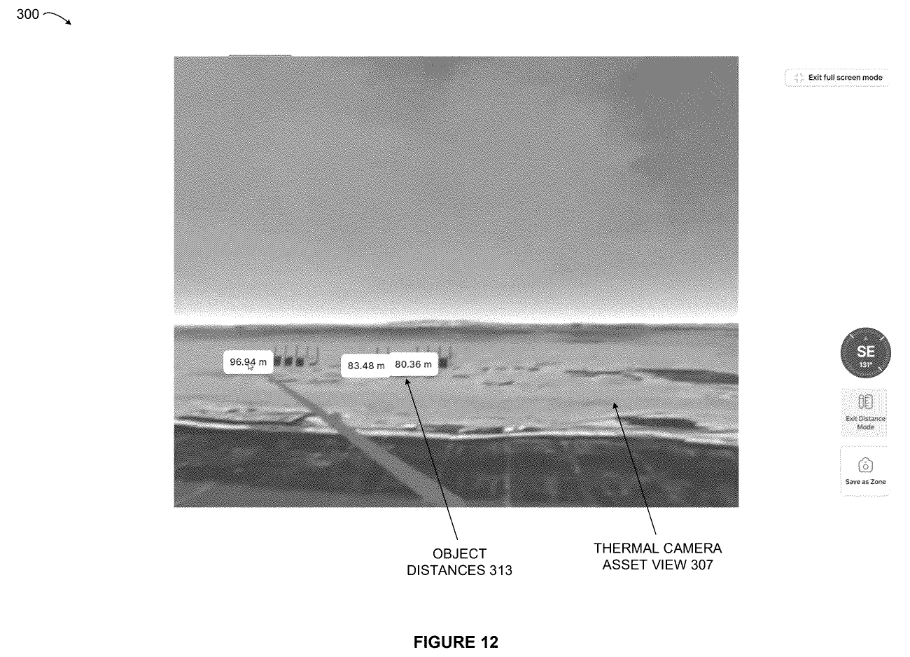

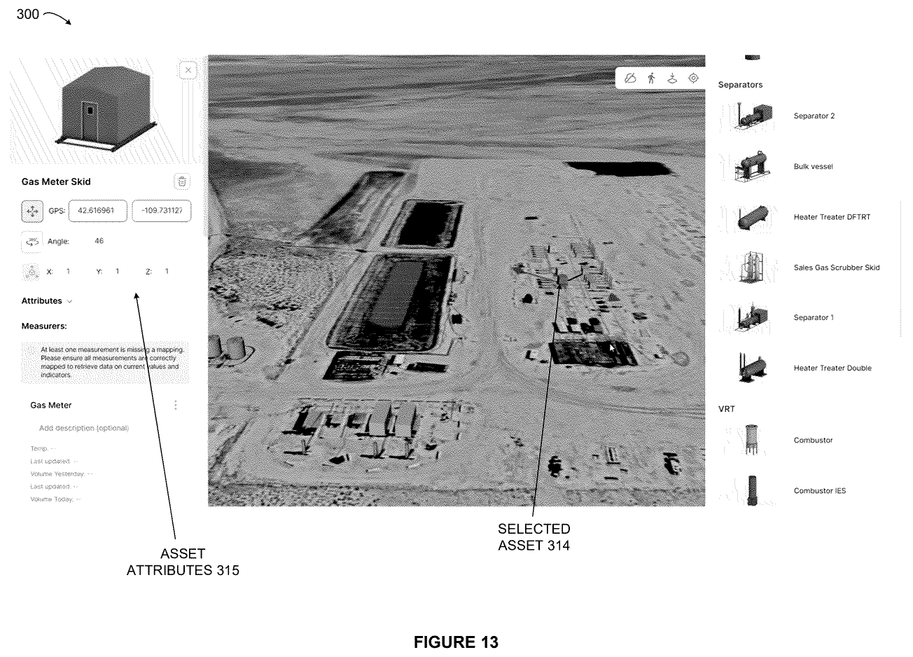

FIG. 12 illustrates an example of user interface 300. In some examples, user interface 300 comprises a zoomed in view of thermal camera's view 307 of 3D map 301. User interface 300 allows a user to select objects within the view of the thermal camera. In response, user interface 300 displays object distances 313 which indicate the distance between the thermal camera and the selected object. FIG. 13 illustrates an example of user interface 300. In some examples, user interface 300 comprises a selected digital equipment model (referred to in this example as selected asset 314 in FIG. 13). In this example, a user has selected a digital model representing a gas meter skit (e.g., structure 115) in the natural gas extraction environment. In response, user interface 300 displays asset attributes 315 for selected asset 314.

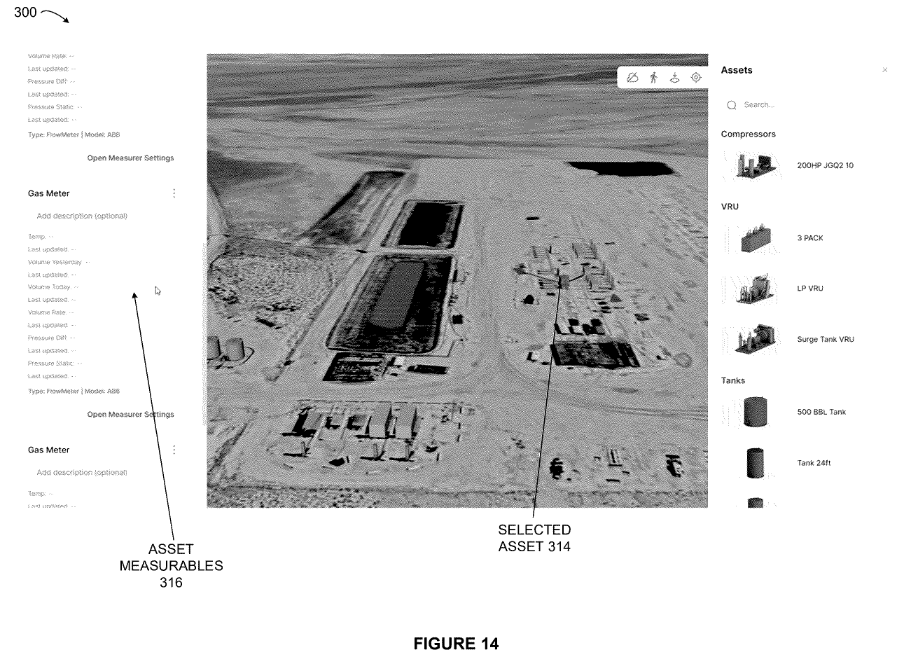

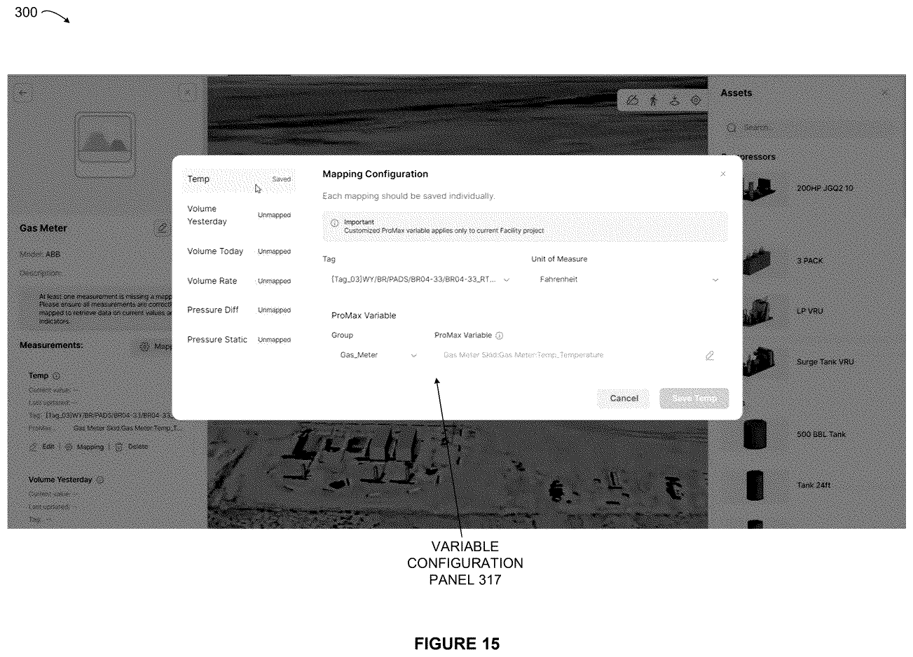

FIG. 14 illustrates an example of user interface 300. In some examples, user interface 300 includes a side panel that allows a user to configure asset measurables 316 for selected asset 314. In this example, selected asset 314 comprises a gas meter and configurable measurables 316 include temperature, volume, volume rate, pressure differential, and static pressure. FIG. 15 illustrates an example of user interface 300. In some examples, user interface 300 includes variable configuration panel 317 to select measurables to be associated with selected asset 314. In this example, selected asset 314 is a gas meter (e.g., the gas meter illustrated in FIG. 14). Variable configuration panel 317 comprises selectable options to map process variables obtained from on-site sensors (referred to as a tag in FIG. 15) to variables in a thermodynamic model (referred to as a ProMax Variable in FIG. 15). Panel 317 allows a user to select their preferred unit of measurement for the process variable. In this example, the user has mapped the process variable tag for gas meter temperature to the thermodynamic model variable for gas meter temperature and selected Fahrenheit as the unit of measurement.

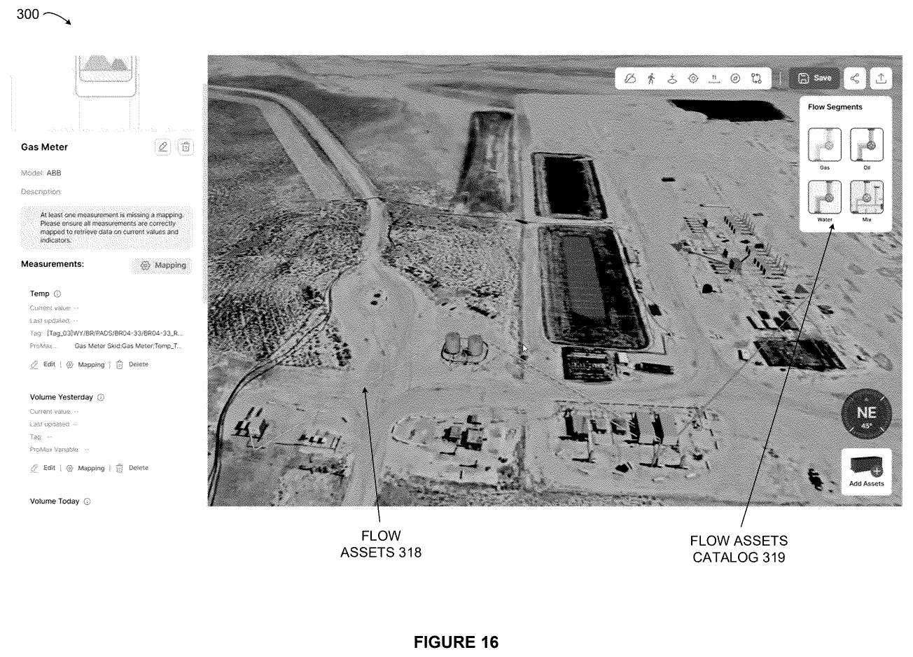

FIG. 16 illustrates an example of user interface 300. In some examples, user interface 300 comprises selectable options display flow 318 segments within the natural gas extraction site. The flow segments carry materials between the assets populated on the 3D map. In this example, the flow assets comprise gas flows, oil flows, water flows, and mixture flows. User interface 300 also includes flow assets catalog 319 to allow a user to select the flow asset type (e.g., gas, oil, water, etc.).

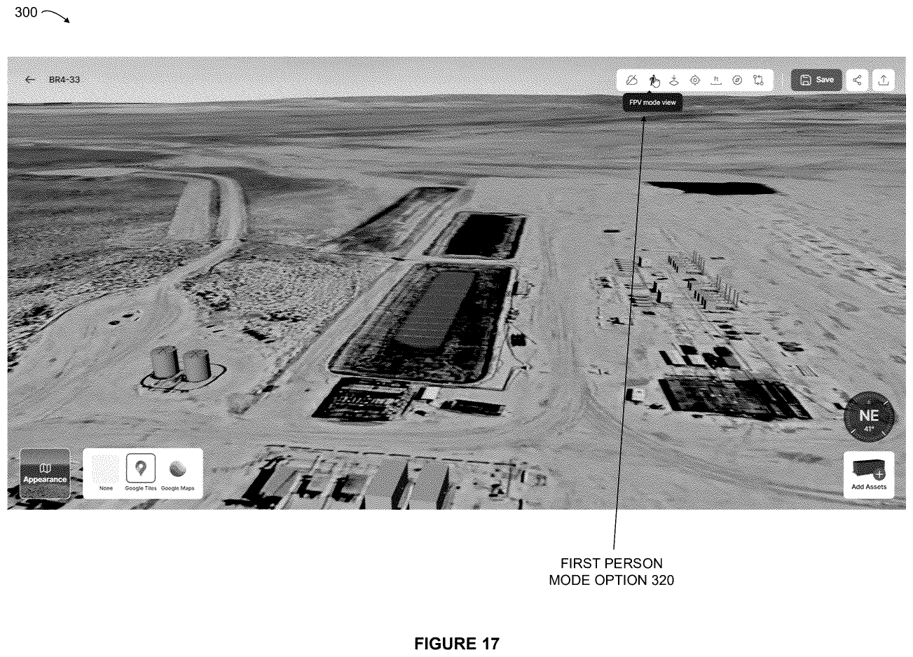

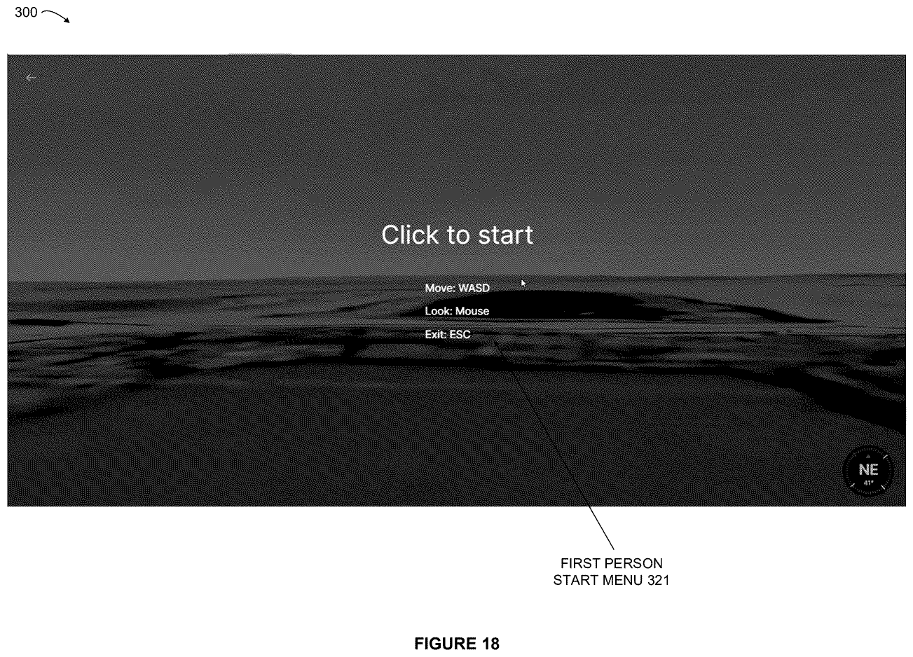

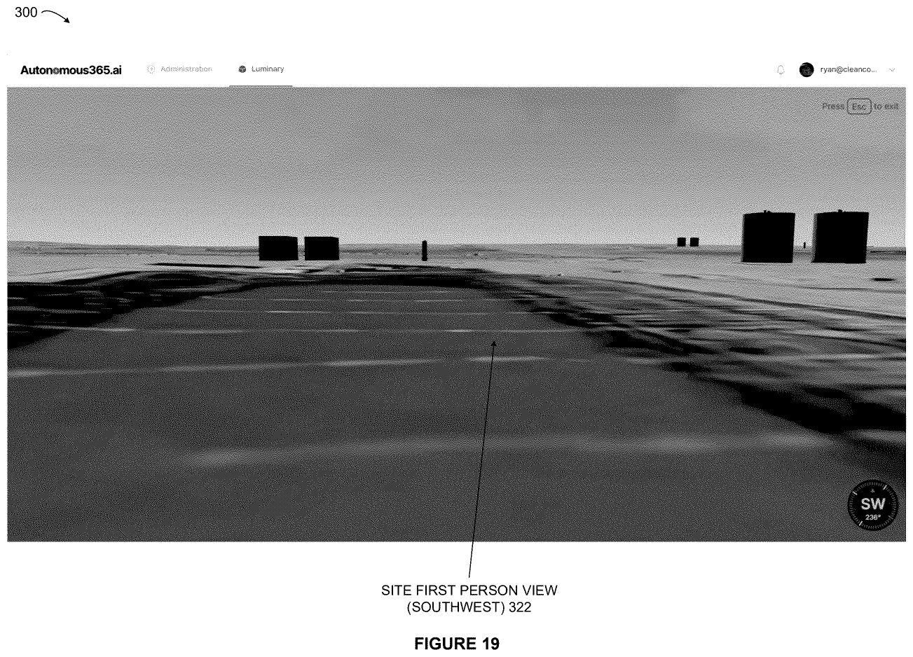

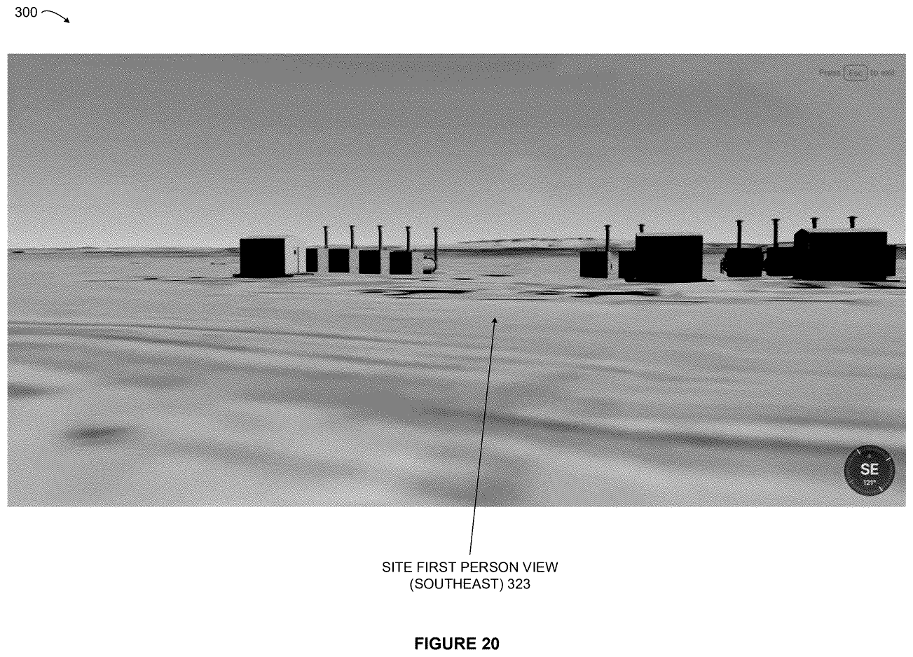

FIG. 17 illustrates an example of user interface 300. In some examples, user interface 300 comprises a selectable option to enter a first-person mode (referred to as first person mode option 320 in FIG. 17). While in first person-mode, a user may navigate the 3D map of the natural gas extraction site as if they were walking at the real-world site. FIG. 18 illustrates an example of user interface 300. In some examples, user interface displays first person mode start menu 321 in response to a user selecting the first-person mode displayed in FIG. 17. A user may select the start menu to begin first-person mode. FIG. 19 illustrates an example of user interface 300 while showing site first person view 322. In some examples, user interface 300 displays 3D map 301 of the natural gas facility from a first-person perspective. A user may move around 3D map 301 within the first person perspective. FIG. 20 illustrates an example of user interface 300 while showing site first person view 323. In some examples, user interface 300 displays 3D map 301 of the natural gas facility from a first-person perspective. In this example, the user has moved their perspective of 3D map 301 from the southwest illustrated in FIG. 20 to the southeast.

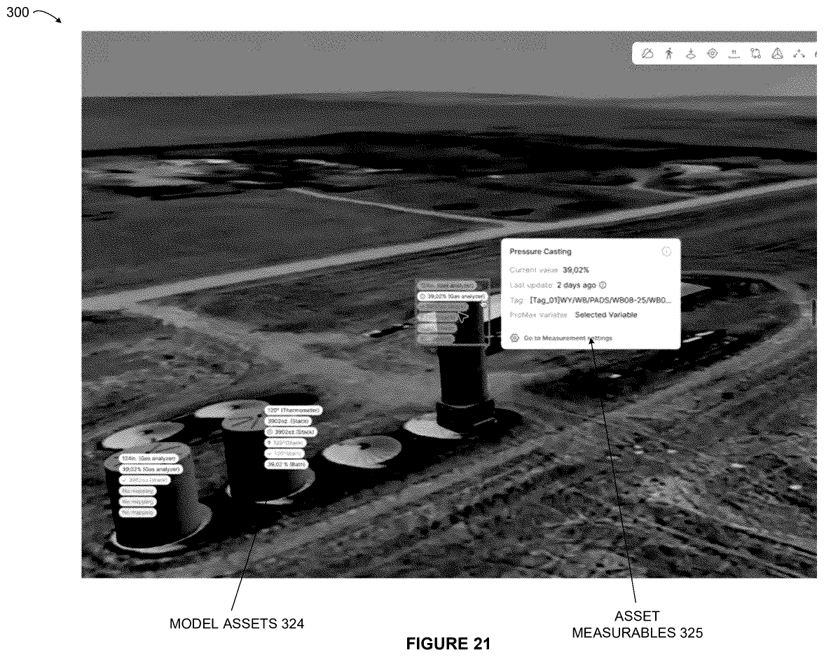

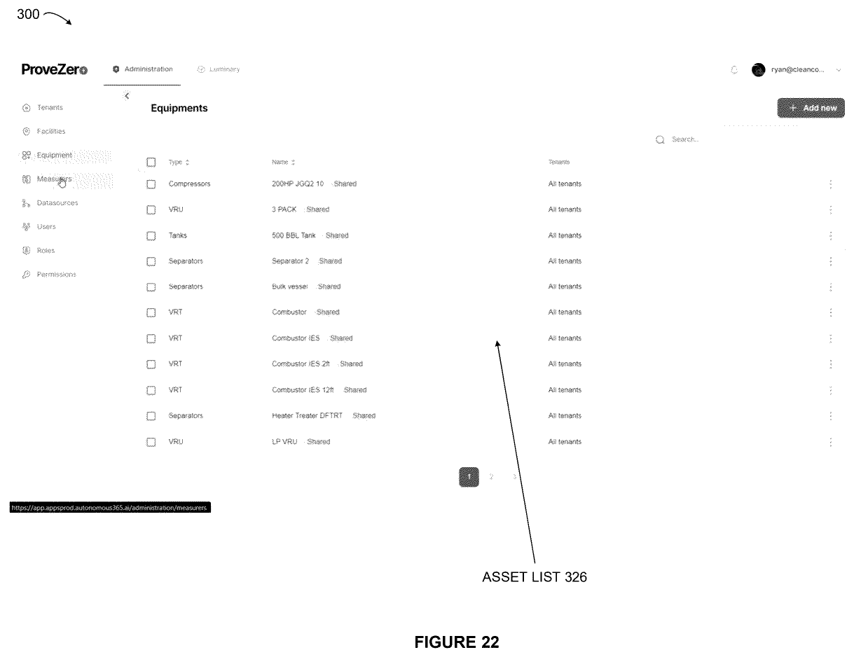

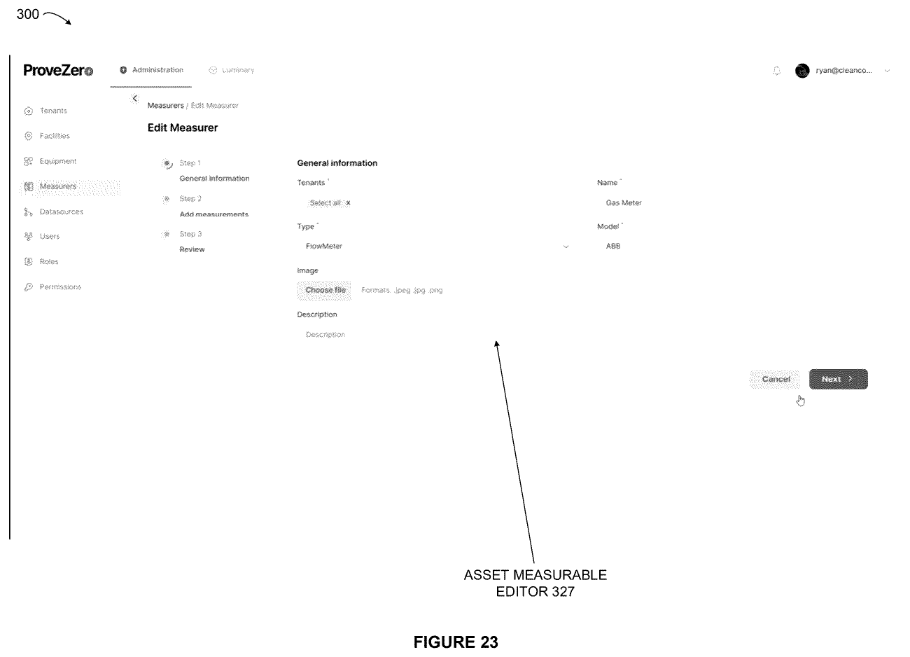

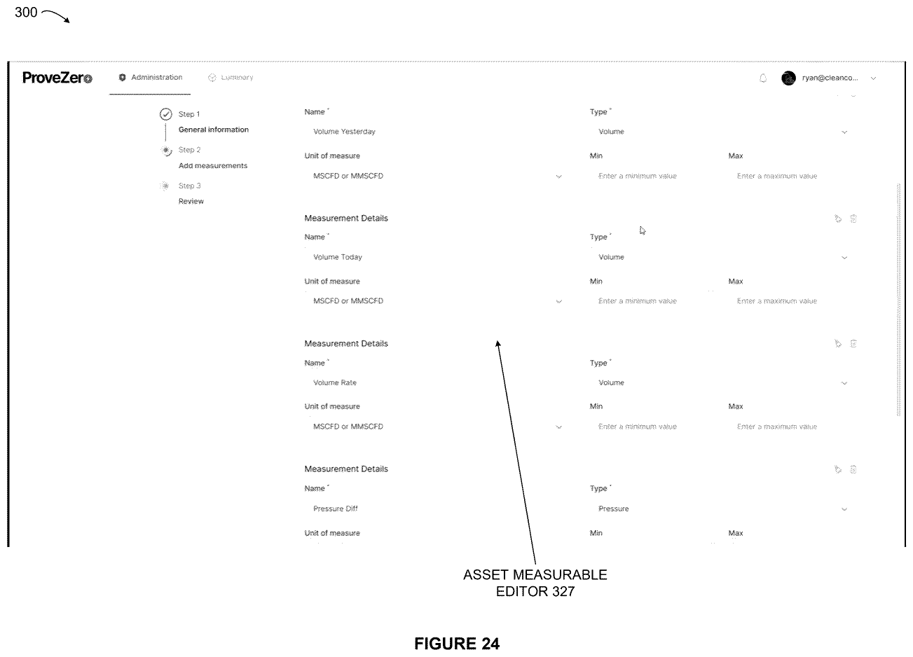

FIG. 21 illustrates an example of user interface 300. In some examples, user interface 300 displays overlays measurables (e.g., process variables referred to as asset measurables 325 in FIG. 21) on assets 324 in 3D site map 301. This allows the user to view the status of the physical devices in the extraction site that correspond to the 3D assets. FIG. 22 illustrates an example of user interface 300. In some examples, user interface 300 includes list 326 that lists assets populated on 3D map 301 of the natural gas extraction site. FIGS. 23 and 24 illustrates an example of user interface 300. In some examples, user interface 300 includes asset measurable editor 327. Editor 327 includes selectable options to edit the measurables associated with the assets populated on the 3D map of the natural gas extraction site.

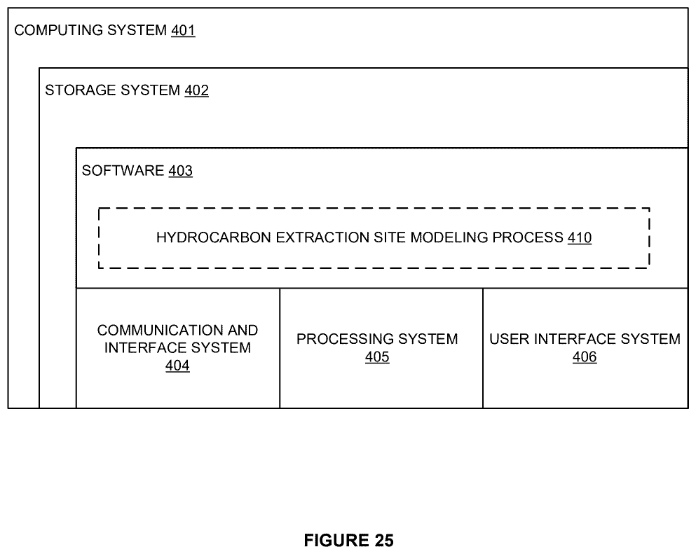

FIG. 25 illustrates computing system 401. Computing system 401 is representative of any system or collection of systems with which the various operational architectures, processes, scenarios, and sequences disclosed herein for modeling hydrocarbon extraction sites. For example, computing system 401 may be representative of sensors 114, monitoring system 116, compute engine 121 and/or any other computing device contemplated herein. Computing system 401 may be implemented as a single apparatus, system, or device or may be implemented in a distributed manner as multiple apparatuses, systems, or devices. Computing system 401 includes, but is not limited to, storage system 402, software 403, communication interface system 404, processing system 405, and user interface system 406. Processing system 405 is operatively coupled with storage system 402, communication interface system 404, and user interface system 406.

Processing system 405 loads and executes software 403 from storage system 402. Software 403 includes and implements hydrocarbon extraction site modeling process 410, which is representative of any of the hydrocarbon extraction site processes described with respect to the preceding Figures, including but not limited to the video imaging, machine learning, leak detection and classification, fill level detection, sensor discrepancy detection, user interface, and extraction site modeling operations described with respect to the preceding Figures. For example, process 410 may be representative of process 200 illustrated in FIG. 2. When executed by processing system 405 to model hydrocarbon extraction sites, software 403 directs processing system 405 to operate as described herein for at least the various processes, operational scenarios, and sequences discussed in the foregoing implementations. Computing system 401 may optionally include additional devices, features, or functionality not discussed for purposes of brevity.

Processing system 405 may comprise a micro-processor and other circuitry that retrieves and executes software 403 from storage system 402. Processing system 405 may be implemented within a single processing device but may also be distributed across multiple processing devices or sub-systems that cooperate in executing program instructions. Examples of processing system 405 include general purpose CPUs, GPUs, DSPs, ASICs, FPGAs, analog computing devices, and logic devices, as well as any other type of processing device, combinations, or variations thereof.

Storage system 402 may comprise any computer readable storage media readable by processing system 405 and capable of storing software 403. Storage system 402 may include volatile, nonvolatile, removable, and/or non-removable media implemented in any method or technology for storage of information, such as computer readable instructions, data structures, program modules, or other data. Examples of storage media include RAM, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 402 may also include computer readable communication media over which at least some of software 403 may be communicated internally or externally. Storage system 402 may be implemented as a single storage device but may also be implemented across multiple storage devices or sub-systems co-located or distributed relative to each other. Storage system 402 may comprise additional elements, such as a controller, capable of communicating with processing system 405 or possibly other systems.

Software 403 (including process 410) may be implemented in program instructions and among other functions may, when executed by processing system 405, direct processing system 405 to operate as described with respect to the various operational scenarios, sequences, and processes illustrated herein. For example, software 403 may include program instructions for obtaining sensor and image data for a natural gas extraction site and loading the obtained data to a 3D model of the extraction site as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 403 may include additional processes, programs, or components, such as operating system software, virtualization software, or other application software. Software 403 may also comprise firmware or some other form of machine-readable processing instructions executable by processing system 405.

In general, software 403 may, when loaded into processing system 405 and executed, transform a suitable apparatus, system, or device (of which computing system 401 is representative) overall from a general-purpose computing system into a special-purpose computing system customized to model hydrocarbon extraction sites. Indeed, encoding software 403 on storage system 402 may transform the physical structure of storage system 402. The specific transformation of the physical structure may depend on various factors in different implementations of this description. Examples of such factors may include, but are not limited to, the technology used to implement the storage media of storage system 402 and whether the computer-storage media are characterized as primary or secondary storage, as well as other factors.

For example, if the computer readable storage media are implemented as semiconductor-based memory, software 403 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 404 may include communication connections and devices that allow for communication with other computing systems (not shown) over communication networks (not shown). Examples of connections and devices that together allow for inter-system communication may include network interface cards, antennas, power amplifiers, radiofrequency circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing system 401 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of networks, or variation thereof. The aforementioned communication networks and protocols are well known and an extended discussion of them is omitted for the sake of brevity.

While some examples provided herein are described in the context of computing devices modeling hydrocarbon extraction sites, it should be understood that the condition systems and methods described herein are not limited to such embodiments and may apply to a variety of other environments and their associated systems. As will be appreciated by one skilled in the art, aspects of the present invention may be embodied as a system, method, computer program product, and other configurable systems. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

What is claimed is:

1. A method to model a hydrocarbon extraction site, the method comprising:
obtaining a topographically accurate map of the hydrocarbon extraction site;
populating the map with digital assets that correspond to equipment and a monitoring system in the hydrocarbon extraction site;
obtaining sensor data for the equipment from sensors in the hydrocarbon extraction site;
obtaining image data depicting the hydrocarbon extraction site from the monitoring system in the hydrocarbon extraction site;
converting the sensor data into a format interpretable by a thermodynamic model and providing the converted sensor data to the thermodynamic model;
receiving an output from the thermodynamic model that comprises process values that depict the operation of the equipment of the hydrocarbon extraction site; and
adding the process values from the output of the thermodynamic model and the image data to corresponding ones of the digital assets to create a model of the hydrocarbon extraction site.

2. The method of claim 1 further comprising generating and displaying a user interface that comprises the model of the hydrocarbon extraction site.

3. The method of claim 1 wherein the digital assets comprise scale models of the equipment and the monitoring system.

4. The method of claim 1 further comprising:
calculating a field of view of the monitoring system in the hydrocarbon extraction site based on a topography of hydrocarbon extraction site, a location of the monitoring system, an elevation of the monitoring system, and locations of the equipment; and
adding the field of view of the monitoring system to the model of the hydrocarbon extraction site.

5. The method of claim 1 wherein the locations of the digital assets in the model of the hydrocarbon extraction site correspond to Global Positioning System (GPS) coordinates of the equipment and the monitoring system.

6. The method of claim 1 further comprising receiving an alert from the monitoring system that indicate a presence of a leak in the equipment in the hydrocarbon extraction site and in response, adding a notification to a corresponding one of the digital assets to indicate the presence of the leak.

7. The method of claim 1 wherein converting the sensor data into the format interpretable by the thermodynamic model and providing the converted sensor data to the thermodynamic model comprises receiving the sensor data in a first format native to the sensors, translating the sensor data from the first format to the format interpretable by the thermodynamic model, and providing the sensor data in the format interpretable by the thermodynamic to the thermodynamic model.

8. The method of claim 1 wherein the sensor data comprises one or more of a flowrate, a fill level, a temperature, a pressure, and a hydrocarbon composition.

9. The method of claim 1 wherein the image data comprises one or more of visible spectrum video and infrared video.

10. The method of claim 1 wherein adding the process values from the output of the thermodynamic model and the image data to the corresponding ones of the digital assets comprises:
overlaying the process values onto the corresponding ones of the digital assets to indicate a process state for the equipment; and
displaying a view of the monitoring system.

11. A system to model a hydrocarbon extraction site, the system comprising:
processing circuitry configured to:
obtain a topographically accurate map of the hydrocarbon extraction site;
populate the map with digital assets that correspond to equipment and a monitoring system in the hydrocarbon extraction site;
obtain sensor data for the equipment from sensors in the hydrocarbon extraction site;
obtain image data depicting the hydrocarbon extraction site from the monitoring system in the hydrocarbon extraction site;
convert the sensor data into a format interpretable by a thermodynamic model and provide the converted sensor data to the thermodynamic model;
receive an output from the thermodynamic model that comprises process values that depict the operation of the equipment of the hydrocarbon extraction site; and
add the process values from the output of the thermodynamic model and the image data to corresponding ones of the digital assets to create a model of the hydrocarbon extraction site.

12. The system of claim 11 wherein the processing circuitry is further configured to generate data for rending a user interface that comprises the model of the hydrocarbon extraction site.

13. The system of claim 11 wherein the digital assets comprise scale models of the equipment and the monitoring system.

14. The system of claim 11 wherein the processing circuitry is further configured to:
calculate a field of view of the monitoring system in the hydrocarbon extraction site based on a topography of hydrocarbon extraction site, a location of the monitoring system, an elevation of the monitoring system, and locations of the equipment; and
add the field of view of the monitoring system to the model of the hydrocarbon extraction site.

15. The system of claim 11 wherein the locations of the digital assets in the model of the hydrocarbon extraction site correspond to Global Positioning System (GPS) coordinates of the equipment and the monitoring system.

16. The system of claim 11 wherein the processing circuitry is further configured to receive an alert from the monitoring system that indicates a presence of a leak in the equipment in the hydrocarbon extraction site and in response, add a notification to a corresponding one of the digital assets to indicate the presence of the leak.

17. The system of claim 11 wherein the processing circuitry is configured to receive the sensor data in a first format native to the sensors, translate the sensor data from the first format to the format interpretable by the thermodynamic model, and provide the sensor data in the format interpretable by the thermodynamic to the thermodynamic model.

18. The system of claim 11 wherein:
the sensor data comprises one or more of a flowrate, a fill level, a temperature, a pressure, and a hydrocarbon composition; and
the image data comprises one or more of visible spectrum video and infrared video.

19. The system of claim 11 wherein the processing circuitry is configured to:
overlay the process values onto the corresponding ones of the digital assets to indicate a process state for the equipment; and
display a view of the monitoring system.

20. A non-transitory computer-readable medium stored thereon instructions to model a hydrocarbon extraction site, that, in response to execution, cause a system comprising a processor to perform operations, the operations comprising:
obtaining a topographically accurate map of the hydrocarbon extraction site;
populating the map with digital assets that correspond to equipment and a monitoring system in the hydrocarbon extraction site;
obtaining sensor data for the equipment from sensors in the hydrocarbon extraction site;
obtaining image data depicting the hydrocarbon extraction site from the monitoring system in the hydrocarbon extraction site;
converting the sensor data into a format interpretable by a thermodynamic model and providing the converted sensor data to the thermodynamic model;
receiving an output from the thermodynamic model that comprises process values that depict the operation of the equipment of the hydrocarbon extraction site; and
adding the process values from the output of the thermodynamic model and the image data to corresponding ones of the digital assets to create a model of the hydrocarbon extraction site.
